(19) United States
(12) Patent Application Publication
(10) Pub. No.: US 2019/0173425 A1
(43) Pub. Date: Jun. 6, 2019

(54) WIDE BAND FREQUENCY OSCILLATOR CIRCUIT AND OSCILLATION METHOD USING RING VOLTAGE CONTROLLED OSCILLATOR

(71) Applicant: Electronics and Telecommunications Research Institute, Daejeon (KR)

(72) Inventors: Seong Mo MOON, Daejeon (KR); In Bok YOM, Daejeon (KR)

(73) Assignee: Electronics and Telecommunications Research Institute, Daejeon (KR)

(21) Appl. No.: 16/158,352

(22) Filed: Oct. 12, 2018

(30) Foreign Application Priority Data
Dec. 4, 2017 (KR) 10-2017-0165035

(51) Int. Cl. H03B 5/12; H03K 3/03

(52) U.S. Cl. CPC H03B 5/124; H03K 3/0315; H03B 5/1296; H03B 5/1293

(57) ABSTRACT

Disclosed is a wide band frequency oscillator circuit and oscillation method using a ring voltage-controlled oscillator (VCO). The frequency oscillator circuit includes a low drop-out (LDO) regulator configured to generate an input voltage of a ring VCO, and the ring VCO connected to the LDO regulator and configured to control an oscillation frequency based on the input voltage, wherein the LDO regulator includes a feedback adjustable resistor.

### CROSS-REFERENCE TO RELATED APPLICATION(S)

This application claims the priority benefit of Korean Patent Application No. 10-2017-0165035 filed on Dec. 4, 2017, in the Korean Intellectual Property Office, the disclosure of which is incorporated herein by reference for all purposes.

### BACKGROUND

### 1. Field

One or more example embodiments relate to a wide band frequency oscillator circuit and oscillation method using a ring voltage-controlled oscillator (VCO).

### 2. Description of Related Art

A ring voltage-controlled oscillator (VCO) is a general VCO easily having a small circuit size and a low power consumption in a low frequency band and a high frequency band. The most significant characteristics of the performance of VCO are a phase noise characteristic and a pushing figure characteristic that minimizes a change in output oscillation frequency with respect to an input frequency.

To improve the phase noise characteristic, the oscillator should generate little noise, and a coupling noise characteristic thereof should be minimized when coupled to a phase locked loop (PLL). In particular, to reduce noise when coupled to the PLL, a loop bandwidth needs to be reduced, and for this, the KVCO characteristic of the VCO needs to decrease.

### SUMMARY

An aspect provides a wide band frequency oscillation technology using a ring voltage-controlled oscillator having a low KVCO characteristic and a low pushing figure characteristic.

According to an aspect, there is provided a frequency oscillator circuit including a low drop-out (LDO) regulator configured to generate an input voltage of a ring voltage-controlled oscillator (VCO), and the ring VCO connected to the LDO regulator and configured to control an oscillation frequency based on the input voltage, wherein the LDO regulator may include a feedback adjustable resistor.

One side of the feedback adjustable resistor may be connected to an output end of the LDO regulator to control the input voltage.

The ring VCO may include a plurality of amplifiers connected in series.

At least one of the plurality of amplifiers may include a voltage-controlled capacitor using a P-type metal oxide semiconductor (PMOS).

The plurality of amplifiers may be configured to control the oscillation frequency using a plurality of input voltages.

The plurality of input voltages may include at least one of a first input voltage for coarse tuning of the oscillation frequency, and a second input voltage for fine tuning of the oscillation frequency.

At least one of the first input voltage and the second input voltage may be an output voltage of the LDO regulator.

According to an aspect, there is provided a frequency oscillation method including generating an input voltage using an LDO regulator, and controlling an oscillation frequency of a ring VCO connected to the LDO regulator based on the input voltage, wherein the LDO regulator may include a feedback adjustable resistor.

One side of the feedback adjustable resistor may be connected to an output end of the LDO regulator, wherein the generating may include controlling the input voltage by adjusting the feedback adjustable resistor.

The ring VCO may include a plurality of amplifiers connected in series.

At least one of the plurality of amplifiers may include a voltage-controlled capacitor using a PMOS.

The plurality of amplifiers may be configured to control the oscillation frequency using a plurality of input voltages.

The controlling of the oscillation frequency may include at least one of performing coarse tuning of the oscillation frequency by adjusting a first input voltage, and performing fine tuning of the oscillation frequency by adjusting a second input voltage, wherein the plurality of input voltages may include the first input voltage and the second input voltage.

At least one of the first input voltage and the second input voltage may be an output voltage of the LDO regulator.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating a frequency oscillator circuit according to an example embodiment;

FIG. 2 is a circuit diagram illustrating the frequency oscillator circuit of FIG. 1;

FIG. 3 is a circuit diagram illustrating a low drop-out (LDO) regulator of FIG. 1;

FIG. 4 is a circuit diagram illustrating a ring voltage-controlled oscillator (VCO) of FIG. 1;

FIG. 5 is a circuit diagram illustrating an amplifier of FIG. 4;

FIG. 6 illustrates a simulation result of output voltages with respect to a change in feedback adjustable resistor of the LDO regulator of FIG. 3; and

FIG. 7 illustrates a simulation result of output frequencies with respect to a change in input voltage of the frequency oscillator circuit of FIG. 1.

### DETAILED DESCRIPTION

The following detailed structural or functional description of example embodiments is provided as an example only and various alterations and modifications may be made to the example embodiments. Accordingly, the example embodiments are not construed as being limited to the disclosure and should be understood to include all changes, equivalents, and replacements within the technical scope of the disclosure.

Various alterations and modifications may be made to the examples. Here, the examples are not construed as limited to the disclosure and should be understood to include all changes, equivalents, and replacements within the idea and the technical scope of the disclosure.

Terms, such as first, second, and the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component. On the contrary, it should be noted that if it is described that one component is “directly connected”, “directly coupled”, or “directly joined” to another component, a third component may be absent. Expressions describing a relationship between components, for example, “between”, directly between”, or “directly neighboring”, etc., should be interpreted to be alike.

The terminology used herein is for the purpose of describing particular examples only and is not to be limiting of the examples. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which examples belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, the example embodiments will be described in detail with reference to the accompanying drawings. However, the scope of the present application is not limited to the example embodiments. In the drawings, like reference numerals are used for like elements.

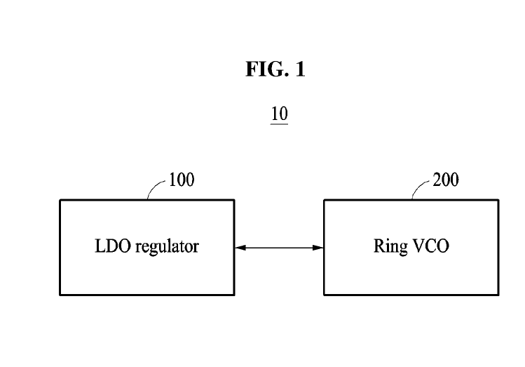

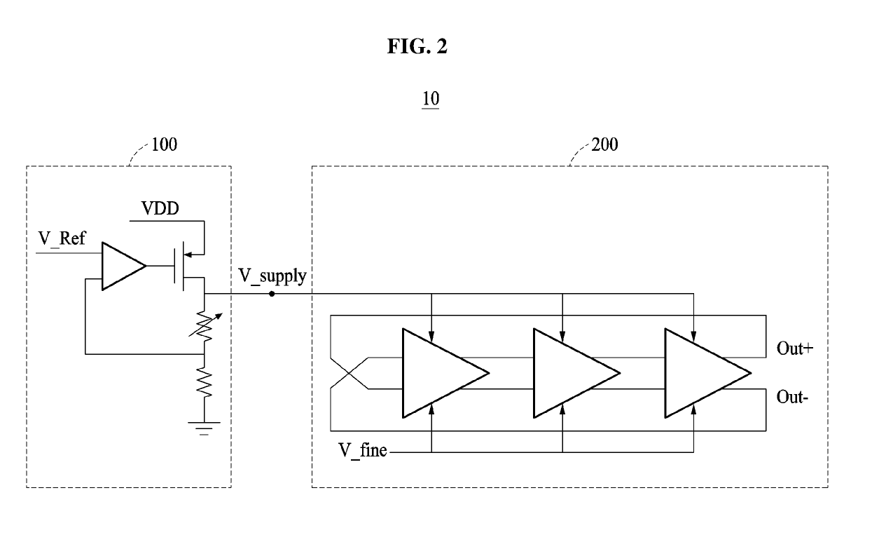

FIG. 1 is a block diagram illustrating a frequency oscillator circuit according to an example embodiment, and FIG. 2 is a circuit diagram illustrating the frequency oscillator circuit of FIG. 1.

Referring to FIGS. 1 and 2, a frequency oscillator circuit 10 may generate an input voltage and generate an oscillation frequency based on the input voltage. The frequency oscillator circuit 10 may generate an oscillation frequency corresponding to a wide band using a low power.

The frequency oscillator circuit 10 may provide a ring voltage-controlled oscillator (VCO) which may be easily applicable to a complementary metal oxide semiconductor (CMOS) process. The frequency oscillator circuit 10 may have a low KVCO characteristic and a wide band frequency variation characteristic.

A KVCO may refer to a gain of the ring VCO. A unit of the KVCO may be megahertz per volt (MHz/V) or gigahertz per volt (GHz/V).

The frequency oscillator circuit 10 may implement a circuit insensitive to a change in characteristic with respect to a power voltage during use after a module assembly using chips or an on-wafer measurement is performed. The characteristic with respect to the power voltage may include a phase noise characteristic and a pushing figure characteristic.

The pushing figure characteristic may refer to a frequency variation of the ring VCO with respect to a change in input voltage.

The frequency oscillator circuit 10 may apply fine tuning and coarse tuning at the same time, thereby having the low KVCO and the wide band variable frequency characteristic. The frequency oscillator circuit 10 may be insensitive to the change in input voltage and have an excellent phase noise characteristic while applying fine tuning and coarse tuning at the same time. The KVCO may refer to a VCO gain. That is, the KVCO may be a value of the frequency variation with respect to a variable voltage (for example, fine tuning).

The frequency oscillator circuit 10 may have a low KVCO characteristic and a variable frequency characteristic in a wide band, and thus may provide a VCO circuit which shows little change in frequency even if the temperature, the power voltage, and the process characteristic change.

The frequency oscillator circuit 10 may lower noise in an oscillator and reduce a coupling noise characteristic when coupled to a phase locked loop (PLL) circuit, thereby improving a phase noise characteristic. For this, the frequency oscillator circuit 10 may reduce a loop bandwidth using an oscillator circuit with a low KVCO characteristic. The loop bandwidth may refer to a frequency bandwidth which determines an in-band noise characteristic of a phase locked state.

The frequency oscillator circuit 10 may include a low drop-out (LDO) regulator 100 and a ring VCO 200.

The frequency oscillator circuit 10 may generate an oscillation signal using the LDO regulator 100 and the ring VCO 200. The frequency oscillator circuit 10 may generate the input voltage using the LDO regulator 100 and control the oscillation frequency based on the input voltage using the ring VCO 200.

By adjusting a feedback adjustable resistor of the LDO regulator 100, the oscillation frequency of the frequency oscillator circuit 10 may be controlled.

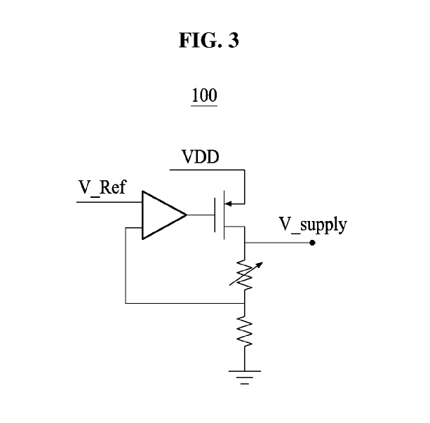

FIG. 3 is a circuit diagram illustrating the LDO regulator of FIG. 1.

Referring to FIG. 3, the LDO regulator 100 may generate an input voltage of the ring VCO 200. The input voltage of the ring VCO 200 may be an output voltage of the LDO regulator 100.

The LDO regulator 100 may generate a constant output voltage although the power voltage is changed. Through this, the LDO regulator 100 may maintain the input voltage of the ring VCO 200 to be constant.

The LDO regulator 100 may include a feedback adjustable resistor. One of the feedback adjustable resistor may be connected to an output end of the LDO regulator 100 to control the input voltage of the ring VCO 200.

In an existing frequency oscillator circuit, a resistor was connected in series between a main amplifier and a regulator. The frequency oscillator circuit 10 may connect the feedback adjustable resistor to the LDO regulator 100, thereby minimizing noise occurring in a power resistor without affecting an IR drop, and minimizing a phase noise characteristic of the ring VCO 200.

The LDO regulator 100 may adjust the feedback adjustable resistor to control the output voltage. For example, the LDO regulator 100 may adjust the output voltage by 3 bits by adjusting the feedback adjustable resistor.

When the LDO regulator 100 uses the feedback adjustable resistor, a resistor may not be connected in series to the input voltage of the ring VCO 200. Thus, thermal noise caused by the resistor connected in series may be minimized, and an effect with respect to the IR drop may be reduced.

The feedback adjustable resistor included in the LDO regulator 100 may be implemented by a general resistor and may not be connected in a form of feedback loop. That is, a connection of the resistor included in the LDO regulator 100 is not limited to the example of FIG. 3.

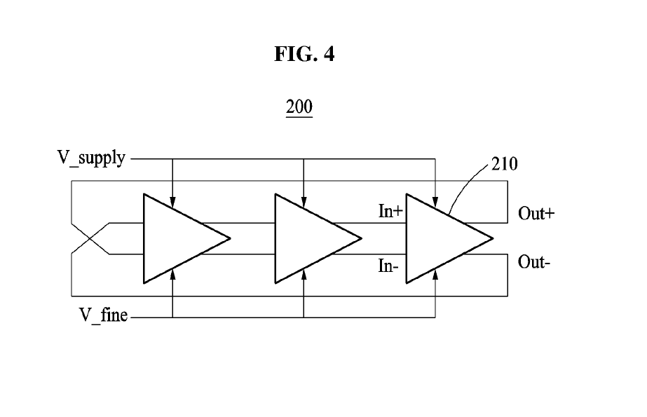

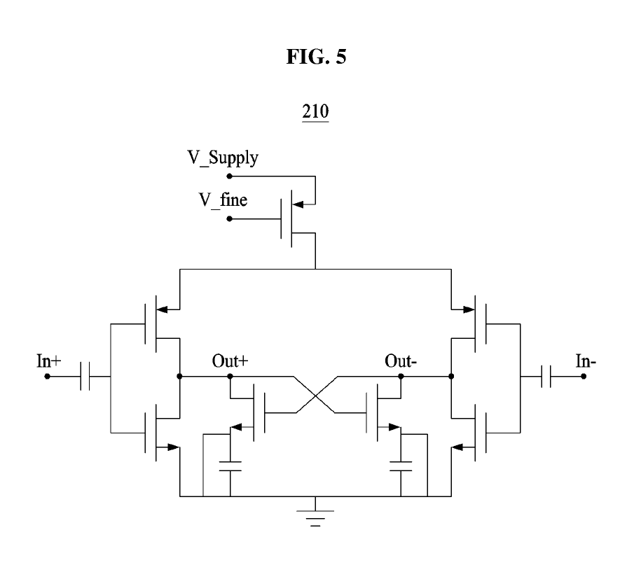

FIG. 4 is a circuit diagram illustrating the ring VCO of FIG. 1, and FIG. 5 is a circuit diagram illustrating the amplifier of FIG. 4.

Referring to FIGS. 4 and 5, the ring VCO 200 may be connected to the LDO regulator 100 and control an oscillation frequency based on an input voltage.

The ring VCO 200 may include a plurality of amplifiers 210 connected in series. The plurality of amplifiers 210 may control the oscillation frequency using a plurality of input voltages. Further, the ring VCO 200 may linearly control an output voltage based on the input voltages.

The plurality of input voltages may include at least one of a first input voltage for coarse tuning of the oscillation frequency and a second input voltage for fine tuning of the oscillation frequency.

For example, the first input voltage may be V_supply, and the second input voltage may be V_fine.

The ring VCO 200 may coarsely change the oscillation frequency by changing the first input voltage V_supply. The ring VCO 200 may finely adjust the oscillation frequency by changing the second input voltage V_fine. The ring VCO 200 may linearly change the oscillation frequency based on the second input voltage V_fine.

At least one of the first input voltage and the second input voltage may be the output voltage of the LDO regulator 100. For example, the first input voltage V_supply may be the output voltage of the LDO regulator 100.

Thus, the LDO regulator 100 may adjust the input voltage of the ring VCO 200 by adjusting the feedback adjustable resistor. The ring VCO 200 may linearly adjust the output voltage based on the input voltage. For example, the ring VCO 200 may adjust the output voltage in a unit of 50 millivolts (mV) in response to a change in feedback adjustable resistor of the LDO regulator 100.

The ring VCO 200 may change the oscillation frequency by changing a gain and a delay.

Although the ring VCO 200 of FIG. 4 includes three amplifiers, the number of amplifiers is not limited thereto. That is, the number of amplifiers may be less than or greater than “3”, as needed.

At least one of the plurality of amplifiers 210 may include a voltage-controlled capacitor using a P-type metal oxide semiconductor (PMOS). The ring VCO 200 may implement the voltage-controlled capacitor using the PMOS, thereby performing fining tuning with respect to a frequency.

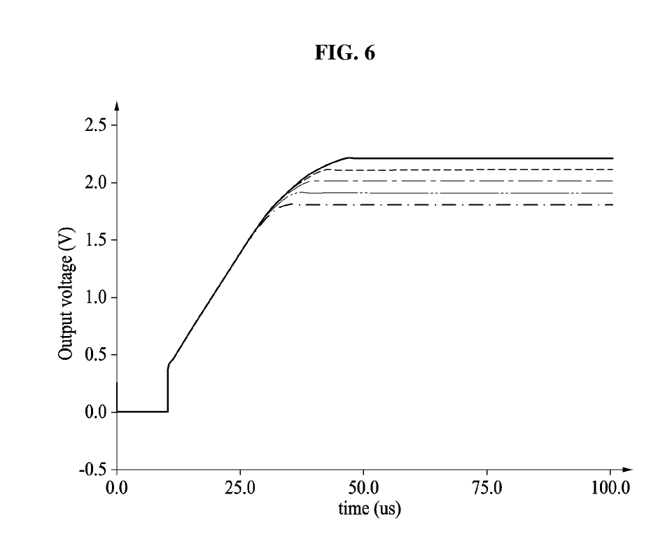

FIG. 6 illustrates a simulation result of output voltages with respect to a change in feedback adjustable resistor of the LDO regulator of FIG. 3.

Referring to FIG. 6, an output voltage of the LDO regulator 100 may be linearly changed with respect to a change in resistance of the feedback adjustable resistor. For example, the LDO regulator 100 may change the output voltage of the LDO regulator 100 in a unit of 50 mV by changing the feedback adjustable resistor.

In the simulation of FIG. 6, it may be learned that the output voltage of the LDO regulator 100 may be changed by 50 mV when the feedback adjustable resistor is changed by a value corresponding to 3 bits.

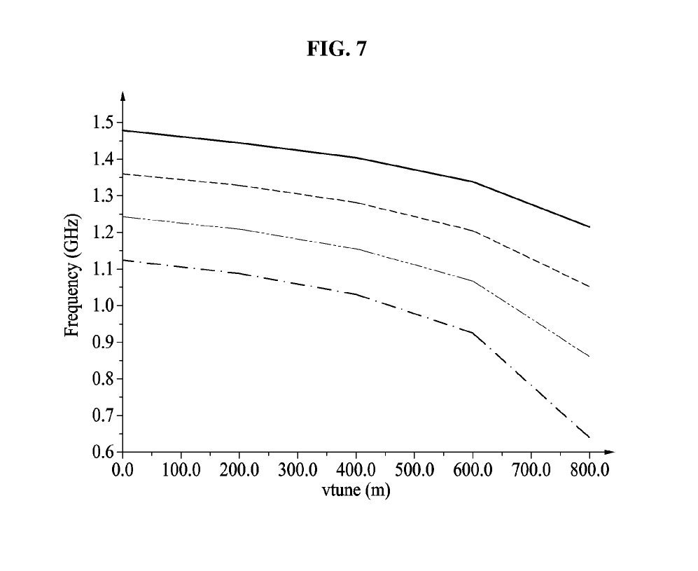

FIG. 7 illustrates a simulation result of output frequencies with respect to a change in input voltage of the frequency oscillator circuit of FIG. 1.

Referring to FIG. 7, the frequency oscillator circuit 10 may control the oscillation frequency while changing V_supply and V_fine at the same time. In a graph of FIG. 7, an axis x corresponds to V_fine, and an axis y denotes a frequency.

In the graph of FIG. 7, a bottom curve corresponds to an example in which V_supply is 1.7 volts (V), and a second curve from the bottom corresponds to an example in which V_supply is 1.75 V. A third curve from the bottom corresponds to an example in which V_supply is 1.8 V, and a top curve corresponds to an example in which V_supply is 1.85 V.

The plurality of curves of FIG. 7 shows that the oscillation frequency differs in response to a value of V_supply. A KVCO denoting a gain of the oscillator may be obtained based on a slope of FIG. 7.

According to the simulation result, it may be verified that the frequency oscillator circuit 10 may increase a variable frequency while decreasing the KVCO.

The components described in the exemplary embodiments of the present invention may be achieved by hardware components including at least one Digital Signal Processor (DSP), a processor, a controller, an Application Specific Integrated Circuit (ASIC), a programmable logic element such as a Field Programmable Gate Array (FPGA), other electronic devices, and combinations thereof. At least some of the functions or the processes described in the exemplary embodiments of the present invention may be achieved by software, and the software may be recorded on a recording medium. The components, the functions, and the processes described in the exemplary embodiments of the present invention may be achieved by a combination of hardware and software.

The processing device described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The method according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A frequency oscillator circuit, comprising:
a low drop-out (LDO) regulator configured to generate an input voltage of a ring voltage-controlled oscillator (VCO); and
the ring VCO connected to the LDO regulator and configured to control an oscillation frequency based on the input voltage,
wherein the LDO regulator comprises a feedback adjustable resistor.

2. The frequency oscillator circuit of claim 1, wherein one side of the feedback adjustable resistor is connected to an output end of the LDO regulator to control the input voltage.

3. The frequency oscillator circuit of claim 1, wherein the ring VCO comprises a plurality of amplifiers connected in series.

4. The frequency oscillator circuit of claim 3, wherein at least one of the plurality of amplifiers comprises a voltage-controlled capacitor using a P-type metal oxide semiconductor (PMOS).

5. The frequency oscillator circuit of claim 3, wherein the plurality of amplifiers is configured to control the oscillation frequency using a plurality of input voltages.

6. The frequency oscillator circuit of claim 5, wherein the plurality of input voltages comprises at least one of:
a first input voltage for coarse tuning of the oscillation frequency; and
a second input voltage for fine tuning of the oscillation frequency.

7. The frequency oscillator circuit of claim 6, wherein at least one of the first input voltage and the second input voltage is an output voltage of the LDO regulator.

8. A frequency oscillation method, comprising:
generating an input voltage using a low drop-out (LDO) regulator; and
controlling an oscillation frequency of a ring voltage-controlled oscillator (VCO) connected to the LDO regulator based on the input voltage,
wherein the LDO regulator comprises a feedback adjustable resistor.

9. The frequency oscillation method of claim 8, wherein one side of the feedback adjustable resistor is connected to an output end of the LDO regulator,
wherein the generating comprises controlling the input voltage by adjusting the feedback adjustable resistor.

10. The frequency oscillation method of claim 8, wherein the ring VCO comprises a plurality of amplifiers connected in series.

11. The frequency oscillation method of claim 10, wherein at least one of the plurality of amplifiers comprises a voltage-controlled capacitor using a P-type metal oxide semiconductor (PMOS).

12. The frequency oscillation method of claim 9, wherein the plurality of amplifiers is configured to control the oscillation frequency using a plurality of input voltages.

13. The frequency oscillation method of claim 12, wherein the controlling of the oscillation frequency comprises at least one of:
performing coarse tuning of the oscillation frequency by adjusting a first input voltage; and
performing fine tuning of the oscillation frequency by adjusting a second input voltage,
wherein the plurality of input voltages comprises the first input voltage and the second input voltage.

14. The frequency oscillation method of claim 13, wherein at least one of the first input voltage and the second input voltage is an output voltage of the LDO regulator.
